(19) United States
(12) Patent Application Publication
(10) Pub. No.: US 2020/0031089 A1
(43) Pub. Date: Jan. 30, 2020

(54) TRANSFER MOLD RELEASING FILM AND METHOD FOR MANUFACTURING MATTE MOLDED BODY

(71) Applicant: DAICEL CORPORATION, Osaka-shi, Osaka (JP)

(72) Inventors: Yoshitaka SUGAWARA, Tokyo (JP); Daisuke USA, Tokyo (JP)

(73) Assignee: DAICEL CORPORATION, Osaka-shi, Osaka (JP)

(21) Appl. No.: 16/603,616

(22) PCT Filed: Mar. 23, 2018
(86) PCT No.: PCT/JP2018/011638

§ 371 Date: Oct. 8, 2019

(30) Foreign Application Priority Data
Jun. 9, 2017 (JP) 2017-114576

(51) Int. Cl. B32B 3/30; B32B 7/02; B32B 23/20; B32B 27/30; B32B 27/28; B32B 27/40; H05K 9/00

(52) U.S. Cl. CPC B32B 3/30; B32B 7/02; B32B 23/20; B32B 27/308; B32B 27/283; B32B 2307/748; H05K 9/00; B32B 2250/02; B32B 2250/03; B32B 2250/24; B32B 2307/538; B32B 27/40

(57) ABSTRACT

A matte molded body is manufactured by forming a concavo-convex shape on a surface to be transferred of a molded body, using a transfer mold releasing film, in which a concavo-convex layer that does not include fine particles of 1 μm or greater and has a transfer surface with an arithmetic average roughness Ra from 0.1 to 2 μm and 60° gloss of less than 5% is formed, on at least one surface of a base layer, the concavo-convex shape being an inverted shape of the transfer surface. The concavo-convex layer may be a cured product of a curable composition including one or more polymer components and one or more curable resin precursor components. At least two components selected from the polymer components and the curable resin precursor components may be phase-separable by wet spinodal decomposition. A haze of the transfer mold releasing film may be 50% or greater. The matte molded body may be an electromagnetic wave shield film. After the concavo-convex shape is transferred using the transfer mold releasing film, the matte molded body having low gloss can be manufactured.

### TECHNICAL FIELD

The present invention relates to a transfer mold releasing film used for manufacturing a matte molded body such as an electromagnetic wave shield film and a method for manufacturing a matte molded body using the releasing film.

### BACKGROUND ART

An electromagnetic wave shield film has been known as a low gloss molded body (matte molded body), which has been modified to have a matte finish by forming a concavo-convex shape on a surface thereof to reduce gloss. The electromagnetic wave shield film is widely used as a film for shielding electromagnetic waves in mobile electronic devices such as smartphones and tablet PCs, and generally has an electromagnetic wave shielding layer formed of metal and the like and a protective layer (hard coat layer) formed of a cured resin and the like. In addition, the electromagnetic wave shield film is often required to have design property in the above applications, and the electromagnetic wave shield film, in which a concavo-convex shape is formed on a surface of the protective layer to reduce the gloss, has been mainly used. As a method for forming a concavo-convex shape on a surface of a protective layer of an electromagnetic wave shield film, a method using a transfer mold releasing film in which a transfer surface has a concavo-convex shape has been widely used. In this method, the concavo-convex shape is formed by transfer, on a surface to be transferred of the protective layer, using s transfer surface of the transfer mold releasing film as a mold (negative type), the concavo-convex shape being an inverted shape of the transfer surface.

In WO 2016/133101 A (Patent Document 1), as a transfer mold releasing film for forming a concavo-convex shape on a protective layer of an electromagnetic wave shield film, a concavo-convex transfer film having a concavo-convex layer including a resin and particles on one side of a substrate film is disclosed. This document describes that the average particle size of the particles is preferably from 1 to 10 μm.

However, in the transfer mold releasing film, since particles are used to form the concavo-convex shape, particles may fall off and may be transferred to a protective layer that is a body to be transferred during transfer.

On the other hand, in JP 2004-231727 A (Patent Document 2), as a substrate film for a transfer foil when performing surface printing and the like on automobile interior/exterior parts, building decorative sheets, bathroom panels, home appliance parts, OA product parts, packaging containers and the like by transfer processing, a surface-treated film in which at least one surface of an unstretched polyester film is subjected to surface treatment of hairline treatment, sandblasting treatment, or satin treatment is disclosed.

However, it has been difficult to achieve low gloss in the surface-treated film. In addition, in the sandblasted surface-treated film, since sand is used, a residue may remain on the surface-treated film and the residue may move to the protective layer during transfer.

JP 2009-276772 A (Patent Document 3) discloses an antiglare film including at least an antiglare layer having a concavo-convex structure on the surface. The antiglare layer is formed of a (meth)acrylic resin and at least one curable resin precursor selected from an epoxy (meth)acrylate, a urethane (meth)acrylate, a polyester (meth)acrylate, a silicone (meth)acrylate, and a multifunctional monomer having at least two polymerizable unsaturated bonds, and the (meth)acrylic resin and the curable resin precursor are phase-separated by spinodal decomposition from a liquid phase, and the precursor is cured.

However, this document does not assume that the antiglare film is used for transfer. In addition, even if the antiglare film is used as a transfer mold releasing film, the gloss is not sufficiently low and the glossiness of less than 5% cannot be realized.

### CITATION LIST

### Patent Document

Patent Document 1: WO 2016/133101 A (Claims)

Patent Document 2: JP 2004-231727 A (Claims, paragraph [0099])

Patent Document 3: JP 2009-276722 A (claim 1)

### SUMMARY OF INVENTION

### Technical Problem

Accordingly, an object of the present invention is to provide a transfer mold releasing film capable of manufacturing a matte molded body having low gloss by a transfer of a concavo-convex shape, and a method for manufacturing a matte molded body using the releasing film.

Another object of the present invention is to provide a transfer mold releasing film capable of preventing impurities such as fine particles and sand from being mixed into a body to be transferred, and a method for manufacturing a matte molded body using the releasing film.

Still another object of the present invention is to provide a transfer mold releasing film capable of manufacturing a matte molded body with high productivity, and a method for manufacturing a matte molded body using the releasing film.

### Solution to Problem

As a result of diligent studies to achieve the above-mentioned problems, the present inventors found that a matte molded body having low gloss can be manufactured by transferring a concavo-convex shape using a transfer mold releasing film, in which a concavo-convex layer that does not include fine particles of 1 μm or greater and has a transfer surface with an arithmetic average roughness Ra from 0.1 to 2 μm and 60° gloss of less than 5% is formed on at least one surface of a base layer, and the present invention has been completed.

That is, a transfer mold releasing film according to an embodiment of the present invention is a transfer mold releasing film for manufacturing a matte molded body with low gloss by transfer, and includes a base layer and a concavo-convex layer that is formed on at least one surface of the base layer and has a surface that is a transfer surface, in which the concavo-convex layer does not include fine particles of 1 μm or greater, and an arithmetic average roughness Ra of the transfer surface is from 0.1 to 2 μm, and 60° gloss of the transfer surface is less than 5%. The concavo-convex layer may be a cured product of a curable composition including one or more polymer components and one or more curable resin precursor components. At least two components selected from the polymer components and the curable resin precursor components may be phase-separable by wet spinodal decomposition. The polymer components may include cellulose esters and a (meth)acrylate-based polymer which may include a polymerizable group. The curable resin precursor components may include urethane (meth)acrylate, silicone (meth)acrylate, and a fluorine-containing curable compound. A haze of the transfer mold releasing film according to an embodiment of the present invention may be 50% or greater. The concavo-convex layer may not include fine particles.

The present invention also includes a method for manufacturing a matte molded body, the method including: performing transferring to form a concavo-convex shape on a surface to be transferred of the molded body using the transfer surface of a transfer mold releasing film as a mold, the concavo-convex shape being an inverted shape of the transfer surface. The matte molded body may be an electromagnetic wave shield film.

### Advantageous Effects of Invention

According to an embodiment of the present invention, it is possible to manufacture the matte molded body having low gloss by transferring the concavo-convex shape using the transfer mold releasing film in which the concavo-convex layer that does not include fine particles of 1 μm or greater and has a transfer surface with an arithmetic average roughness Ra from 0.1 to 2 μm and 60° gloss of less than 5% is formed on at least one surface of the base layer. In addition, the concavo-convex layer is formed with the cured product of the curable composition including one or more polymer components and one or more curable resin precursor components, and thus inclusion of impurities such as fine particles and sand into the body to be transferred can be suppressed. In addition, in a case where the body to be transferred (matte molded body) is formed of the curable resin, the transfer mold releasing film has a suitable adherence prior to curing of the curable resin and can be easily removed after curing. Thus, the transfer mold releasing film has an excellent workability, and the matte molded body can be manufactured with high productivity.

### DESCRIPTION OF EMBODIMENTS

### Base Layer

A transfer mold releasing film according to an embodiment of the present invention includes a base layer. The base layer is not particularly limited as long as it can support a concavo-convex layer, and may be formed of an organic material or an inorganic material. When the concavo-convex layer is formed of a photocurable composition, the base layer is preferably formed of a transparent material from the viewpoint of productivity of the concavo-convex layer. The transparent material may be an inorganic material such as glass, but an organic material is widely used from the viewpoint of strength and moldability. Examples of the organic material include a cellulose derivative, polyester, polyamide, polyimide, polycarbonate, and a (meth)acrylate polymer. Among those, the cellulose ester, the polyester, and the like are widely used.

Examples of the cellulose ester include cellulose acetate such as cellulose triacetate (TAC), and cellulose acetate C₃₋₄ acylate such as cellulose acetate propionate and cellulose acetate butyrate. Examples of the polyester include polyalkylenearylates such as polyethylene terephthalate (PET) and polyethylene naphthalate (PEN).

Among those, poly C₂₋₄ alkylene C₆₋₁₂ arylate such as PET and PEN is preferred from the viewpoint of an excellent balance in mechanical properties, transparency or the like.

The base layer may be subjected to surface treatment (for example, corona discharge treatment, flame treatment, plasma treatment, ozone or ultraviolet irradiation treatment, or the like), and may have an easily adhesive layer.

An average thickness of the base layer may be 10 μm or greater, for example, from 12 to 500 μm, preferably from 20 to 300 μm, and more preferably about from 30 to 200 μm.

### Concavo-Convex Layer

The transfer mold releasing film according to an embodiment of the present invention has a concavo-convex layer that is formed on at least one surface of the base layer and has a surface that is a transfer surface. The concavo-convex layer may be formed on at least one surface of the base layer or may also be formed on both surfaces thereof, but is usually formed on one surface thereof. The surface of the concavo-convex layer becomes a transfer surface having a concavo-convex shape, and can be used to form a concavo-convex shape that is inverted on a surface to be transferred by a concavo-convex transfer.

The arithmetic average surface roughness Ra of the transfer surface of such a concavo-convex layer is from 0.1 to 2 μm, preferably from 0.2 to 1.5 μm (for example, from 0.25 to 1 μm), and more preferably about from 0.3 to 0.8 μm (in particular, from 0.4 to 0.6 μm). In a case where Ra is too small, the convex shape becomes smooth, and the matte molded body cannot be manufactured. In a case where Ra is too large, peeling characteristic is deteriorated and the productivity of the matte molded body is reduced.

In the present specification and claims, the arithmetic average surface roughness Ra can be measured using a contact type surface roughness meter (“surfcom 570A” available from Tokyo Seimitsu Co., Ltd.) in accordance with JIS B0601.

60° gloss of the transfer surface of the concavo-convex layer is less than 5% (for example, from 0.1 to 4.9%), preferably from 1 to 4.5% (for example, from 1.5 to 4.2%), and more preferably about from 2 to 4% (in particular, from 2.5 to 3.5%). If the 60° gloss is too large, the matte molded body cannot be manufactured.

In the present specification and claims, the 60° gloss can be measured using a gloss meter (“IG-320” available from Horiba, Ltd.) in accordance with JIS K7105.

Although the concavo-convex layer has the above-mentioned arithmetic average surface roughness Ra and the 60° gloss, the concavo-convex layer does not include fine particles of 1 μm or greater. Therefore, inclusion of the fine particles into the body to be transferred can be suppressed. In addition, the concavo-convex layer preferably does not include fine particles themselves (fine particles including the ones smaller than 1 μm).

In the present specification and claims, concavo-convex layer including no fine particles (or fine particles of 1 μm or greater), encompasses a concavo-convex layer including a minute amount of fine particles at an impurity level that does not affect the gloss (for example, a concavo-convex layer including 1% by weight or less of fine particles with respect to the entire concavo-convex layer).

Such a concavo-convex layer that does not include fine particles is a cured product of a curable composition including one or more polymer components and one or more curable resin precursor components, and a surface (transfer surface) of the concavo-convex layer may have a concavo-convex shape formed by spinodal decomposition (wet spinodal decomposition) from a liquid phase. Specifically, the surface (transfer surface) may have a concavo-convex shape formed by the phase separation, which proceeds through the spinodal decomposition as the concentration of a curable composition increases in the process of evaporating or removing the solvent from the liquid phase of the composition by drying or the like, wherein the composition (mixed liquid) includes one or more polymer components, and one or more curable resin precursor components.

### Polymer Component

As the polymer component, a thermoplastic resin (including a thermoplastic resin having a polymerizable group) is usually used. The thermoplastic resin is not particularly limited as long as it has high transparency and can form the above-mentioned surface concavo-convex shape by the spinodal decomposition, but examples of the thermoplastic resin include a styrene-based resin, a (meth)acrylate polymer, an organic acid vinyl ester polymer, a vinyl ether-based polymer, a halogen-containing resin, polyolefin (including alicyclic polyolefin), polycarbonate, polyester, polyamide, thermoplastic polyurethane, a polysulfone-based resin (polyether sulfone, polysulfone), a polyphenylene ether-based resin (polymer of 2,6-xylenol), a cellulose derivative (cellulose esters, cellulose carbamates, cellulose ethers), a silicone resin (polydimethylsiloxane, polymethylphenylsiloxane), and rubber or elastomer (diene rubber such as polybutadiene and polyisoprene, a styrene-butadiene copolymer, an acrylonitrile-butadiene copolymer, acrylic rubber, urethane rubber, and silicone rubber). These thermoplastic resins can be used alone or in combination of two or more.

A glass transition temperature of the polymer component can be selected, for example, from the range of from −100° C. to 250° C., preferably from −50° C. to 230° C., and more preferably about from 0 to 200° C. (for example, about from 50 to 180° C.). From the viewpoint of surface hardness, the glass transition temperature is advantageously 50° C. or higher (for example, about from 70 to 200° C.), and preferably from 100° C. or higher (for example, about from 100 to 170° C.). A weight average molecular weight of the polymer component can be selected, for example, from the range of 1000000 or less and preferably about from 1000 to 500000. The weight average molecular weight of the polymer component can be measured by, for example, gel permeation chromatography (GPC) based on calibration using polystyrene.

Among these polymer components, the polymer component may have a polymerizable group and is preferably a combination of the (meth)acrylate-based polymer and the cellulose esters from the viewpoint of easily forming the concavo-convex shape having low gloss. When the (meth)acrylate-based polymer and the cellulose esters are combined as a polymer component, the (meth)acrylate-based polymer and the cellulose esters are incompatible with each other around the drying temperature, and thus the phase separation can be made by the wet spinodal decomposition.

As the (meth)acrylate polymer, a homopolymer or a copolymer of a (meth)acrylate monomer, or a copolymer of a (meth)acrylate monomer and a copolymerizable monomer can be used. Examples of the (meth)acrylate monomer include: (meth)acrylic acid; C₁₋₁₀ alkyl (meth)acrylate such as methyl (meth)acrylate, ethyl (meth)acrylate, butyl (meth)acrylate, t-butyl (meth)acrylate, isobutyl (meth)acrylate, hexyl (meth)acrylate, octyl (meth)acrylate, and 2-ethylhexyl (meth)acrylate; aryl (meth)acrylate such as phenyl (meth)acrylate; hydroxyalkyl (meth)acrylates such as hydroxyethyl (meth)acrylate and hydroxypropyl (meth)acrylate; glycidyl (meth)acrylate; N,N-dialkylaminoalkyl (meth)acrylate; (meth)acrylonitrile; and (meth)acrylate having an alicyclic hydrocarbon group such as tricyclodecane. Examples of the copolymerizable monomer include the styrene monomer, a vinyl ester-based monomer, maleic anhydride, maleate, and fumarate. These monomers can be used alone or in combination of two or more.

Examples of the (meth)acrylate-based polymer include poly(meth)acrylate ester such as polymethylmethacrylate, a methylmethacrylate-(meth)acrylate copolymer, a methylmethacrylate-(meth)acrylate ester copolymer, a methylmethacrylate-acrylate ester-(meth)acrylate copolymer, and a (meth)acrylate ester-styrene copolymer (MS resin). Among those, poly C₁₋₆ alkyl(meth)acrylate such as poly methyl(meth)acrylate, and in particular, a methyl methacrylate-based polymer composed of methylmethacrylate as a main component (from 50 to 100% by weight, and preferably about from 70 to 100% by weight) is preferred.

The (meth)acrylate-based polymer may be a polymer having a polymerizable group involved in a curing reaction. When the (meth)acrylate-based polymer has the polymerizable group, a mechanical strength of the concavo-convex layer can be improved. The (meth)acrylate-based polymer may have the polymerizable group on a main chain or on a side chain. The polymerizable group may be introduced into the main chain by copolymerization or co-condensation, but is usually introduced into the side chain. Examples of the polymerizable group include a C₂₋₆ alkenyl group such as vinyl, propenyl, isopropenyl, butenyl, and allyl, a C₂₋₆ alkynyl group such as ethynyl, propynyl, and butynyl, and a C₂₋₆ alkenylidene group such as vinylidene, a group such as (meth)acryloyl group, having a polymerizable group thereof.

Examples of the method for introducing a polymerizable group into a side chain include a method in which a (meth)acrylate-based polymer having a functional group such as a reactive group and a condensable group is reacted with a polymerizable compound having a group that is reactive with the functional group. For the (meth)acrylate-based polymer having the functional group, examples of the functional group include a carboxyl group or an acid anhydride group thereof, a hydroxyl group, an amino group, and an epoxy group.

Examples of the polymerizable compound include a polymerizable compound having an epoxy group or a hydroxyl group, an amino group, an isocyanate group, and the like in the case of a thermoplastic resin having a carboxyl group or an acid anhydride group thereof. Among those, the polymerizable compound having the epoxy group, for example, epoxycyclo C₅₋₈ alkenyl (meth)acrylate such as epoxycyclohexenyl (meth)acrylate, glycidyl (meth)acrylate, and allylglycidylether, are widely used.

Representative examples include a combination of a (meth)acrylate-based polymer ((meth)acrylate-(meth)acrylate ester copolymer and the like) having a carboxyl group or an acid anhydride group thereof, and epoxy group-containing (meth)acrylate (epoxycycloalkenyl (meth)acrylate, glycidyl (meth)acrylate, and the like). Specifically, a polymer in which a polymerizable unsaturated group is introduced into a part of carboxyl groups of a (meth)acrylate polymer, for example, a (meth)acrylic copolymer (cyclomer-P available from Daicel Corporation) in which a polymerizable group (photopolymerizable unsaturated group) is introduced into a side chain by reacting an epoxy group of 3,4-epoxycyclohexenylmethyl acrylate with a part of carboxyl groups of a (meth)acrylate-(meth)acrylate ester copolymer can be used.

The amount of the polymerizable group introduced into the (meth)acrylate-based polymer is, for example, from 0.001 to 10 moles, preferably from 0.01 to 5 moles, and more preferably about from 0.02 to 3 moles with respect to 1 kg of the (meth)acrylate polymer.

Examples of the cellulose esters include aliphatic organic acid ester (cellulose acetates such as cellulose diacetate and cellulose triacetate; C₁₋₆ organic acid ester such as cellulose propionate, cellulose butyrate, cellulose acetate propionate, and cellulose acetate butyrate), aromatic organic acid esters (C₇₋₁₂ aromatic carboxylic acid esters such as cellulose phthalate and cellulose benzoate), inorganic acid esters (for example, cellulose phosphate, cellulose sulfate, and the like), and the cellulose esters may be mixed acid esters such as acetic acid and cellulose nitrate. These cellulose esters can be used alone or in combination of two or more. Among those, cellulose C2-4 acylate such as cellulose diacetate, cellulose triacetate, cellulose acetate propionate, and cellulose acetate butyrate is preferred, and cellulose acetate C₃₋₄ acylate such as cellulose acetate propionate is particularly preferred.

A weight ratio of the (meth)acrylate-based polymer and the cellulose esters is, for example, as the ratio [(meth)acrylate polymer/cellulose ester], from 50/50 to 99/1, preferably from 60/40 to 90/10, and more preferably about from 70/30 to 85/15 (in particular, from 80/20 to 90/10).

### Curable Resin Precursor Component

The curable resin precursor component is a compound having a functional group that undergoes a reaction by heat, active energy rays (such as ultraviolet rays or electron beams) and the like, and various curable compounds which undergo curing or crosslinking by heat, active energy rays or the like and capable of forming a resin (in particular, cured or crosslinked resin) can be used. Examples of the curable resin precursor component include a thermosetting compound or a resin [low molecular weight compounds having an epoxy group, a polymerizable group, an isocyanate group, an alkoxysilyl group, a silanol group, and the like (for example, an epoxy resin, an unsaturated polyester resin, a urethane resin, and a silicone resin)], a photocurable compound which can be cured by active rays such as ultraviolet rays (ultraviolet curable compounds such as photocurable monomer and oligomer), and the photocurable compound may be an electron beam (EB) curable compound. Note that the photocurable compound such as a photocurable monomer, a photocurable oligomer, and a photocurable resin that may have a low molecular weight may be simply referred to as a “photocurable resin”.

Examples of the photocurable compound include a monomer and an oligomer (or resin, in particular, low molecular weight resin).

Examples of the monomer include monofunctional monomers [(meth)acrylate-based monomers such as (meth)acrylate ester, vinyl-based monomers such as vinylpyrrolidone, (meth)acrylate having a bridged cyclic hydrocarbon group such as isobornyl (meth)acrylate and adamantyl (meth)acrylate], and a multifunctional monomer having at least two polymerizable unsaturated bonds [alkylene glycol di(meth)acrylates such as ethylene glycol di(meth)acrylate, propylene glycol di(meth)acrylate, butanediol di(meth)acrylate, neopentyl glycol di(meth)acrylate, and hexanediol di(meth)acrylate; (poly)oxyalkylene glycol di(meth)acrylates such as diethylene glycol di(meth)acrylate, dipropylene glycol di(meth)acrylate, polyoxytetramethylene glycol di(meth)acrylate; di(meth)acrylates having a crosslinking cyclic hydrocarbon group such as tricyclodecane dimethanol di(meth)acrylate and adamantane di(meth)acrylate; and a multifunctional monomer having about 3 to 6 polymerizable unsaturated bonds such as glycerin tri(meth)acrylate, trimethylolpropane tri(meth)acrylate, trimethylolethane tri(meth)acrylate, pentaerythritol tri(meth)acrylate, ditrimethylolpropane tetra(meth)acrylate, pentaerythritol tetra(meth)acrylate, dipentaerythritol penta(meth)acrylate, dipentaerythritol hexa(meth)acrylate].

Examples of the oligomer or the resin include (meth)acrylate of a bisphenol A-alkylene oxide adduct, epoxy (meth)acrylate [bisphenol A type-epoxy (meth)acrylate, and novolac-type epoxy (meth)acrylate], polyester (meth)acrylate [for example, aliphatic polyester-type (meth)acrylate, and aromatic polyester-type (meth)acrylate], (poly)urethane (meth)acrylate [polyester-type urethane (meth)acrylate, and polyether-type urethane (meth)acrylate], and silicone (meth)acrylate.

These precursor components can be used alone or in combination of two or more. Among those, the urethane (meth)acrylate and the silicone (meth)acrylate are preferred.

In addition, the curable resin precursor component may include a fluorine atom or a filler from the viewpoint of improving peeling characteristic of the concavo-convex layer.

Examples of the precursor component (fluorine-containing curable compounds) containing the fluorine atom include fluorides of the monomer and the oligomer, for example, fluorinated alkyl (meth)acrylate [for example, perfluorooctyl ethyl (meth)acrylate, and trifluoroethyl (meth)acrylate], fluorinated (poly)oxyalkylene glycol di(meth)acrylate [for example, fluoroethylene glycol di(meth)acrylate, and fluoropropylene glycol di(meth)acrylate], a fluorine-containing epoxy resin, and a fluorine-containing urethane-based resin. Among those, a fluoropolyether compound having a (meth)acryloyl group is preferred.

In the precursor component including the filler, examples of the filler include inorganic fine particles such as silica particles, titania particles, zirconia particles, and alumina particles, organic fine particles such as crosslinked (meth)acrylate-based polymer particles, and crosslinked styrene resin particles. These fillers can be used alone or in combination of two or more. Among these fillers, nanometer-sized silica particles (silica nanoparticles) are preferable from the viewpoint of easily forming a low-gloss concavo-convex shape. The silica nanoparticles are preferably solid silica nanoparticles from the viewpoint that the yellowness of a light diffusion film can be suppressed. In addition, an average particle diameter of the silica nanoparticles is, for example, from 1 to 800 nm, preferably from 3 to 500 nm, and more preferably about from 5 to 300 nm. The ratio of the filler (in particular, silica nanoparticles) may be about from 10 to 90% by weight, for example, from 20 to 80% by weight, preferably from 30 to 70% by weight, and more preferably about from 40 to 60% by weight with respect to the entire curable resin precursor component.

The precursor component including the filler may be, for example, inorganic particles (for example, silica particles whose surface is modified with a silane coupling agent having a polymerizable group) which has a polymerizable group on a surface thereof, and may be a photocurable compound containing silica nanoparticles [in particular, multifunctional (meth)acrylate, urethane (meth)acrylate, silicone (meth)acrylate containing silica nanoparticles]. Among those, the silicone (meth)acrylate containing the silica nanoparticles is preferred.

These photocurable compounds can be used alone or in combination of two or more. Among those, the photocurable compound that can be cured in a short time, for example, an ultraviolet curable compound (monomer, oligomer, and resin that may have a low molecular weight), and an EB curable compound. In particular, the practically advantageous resin precursor is an ultraviolet curable resin. In addition, to improve resistance such as scratch resistance, the photocurable resin is preferably a compound having 2 or more (for example, from 2 to 30, preferably from 5 to 25, more preferably from 10 to 20, and particularly about from 12 to 18) polymerizable unsaturated bonds in the molecule.

A weight average molecular weight of the curable resin precursor component is not particularly limited, but in consideration of compatibility with the polymer, the weight average molecular weight may be 5000 or less, for example, from 1000 to 4000, preferably from 1500 to 3000, and more preferably about from 2000 to 2500 in gel permeation chromatography (GPC), based on calibration using polystyrene.

The curable resin precursor component may further include a curing agent depending on the type of the curable resin precursor component. For example, the thermosetting resin may include a curing agent such as amines and polyvalent carboxylic acids, and the photocurable resin may include a photopolymerization initiator. Examples of the photopolymerization initiator include the known components such as acetophenones or propiophenones, benzyls, benzoins, benzophenones, thioxanthones, and acylphosphine oxides. The ratio of a curing agent such as the photopolymerization initiator is from 0.1 to 20% by weight, preferably from 0.5 to 10% by weight, and more preferably about from 1 to 8% by weight with respect to the entire curable resin precursor component.

The curable resin precursor component may further include a curing accelerator. For example, the photocurable resin may include a photocuring accelerator, for example, tertiary amines (such as a dialkylaminobenzoate), and a phosphine-based photopolymerization accelerator.

Among these curable resin precursor components, multifunctional (meth)acrylate (for example, (meth)acrylate having about from 2 to 8 polymerizable groups), epoxy (meth)acrylate, polyester (meth)acrylate, urethane (meth)acrylate, silicone (meth)acrylate, and the like are preferred, and a combination of urethane (meth)acrylate, silicone (meth)acrylate, and a fluorine-containing curable compound is particularly preferable from the viewpoint that low gloss concavo-convex shape can be formed and peeling characteristic of the transfer surface can also be improved.

When these components are combined, the ratio of silicone (meth)acrylate is, for example, from 0.1 to 10 parts by weight, preferably from 0.5 to 5 parts by weight, and more preferably about from 1 to 3 parts by weight (in particular, from 1.2 to 2 parts by weight) based on 100 parts by weight of urethane (meth)acrylate. In addition, the ratio of the fluorine-containing curable compound is, for example, from 0.01 to 5 parts by weight, preferably from 0.1 to 1 part by weight, and more preferably about from 0.15 to 0.5 parts (in particular, from 0.2 to 0.3 parts by weight) with respect to 100 parts by weight of urethane (meth)acrylate.

The ratio (weight ratio) between the polymer component and the curable resin precursor component is not particularly limited, and can be selected, for example, as the ratio [the polymer component/the curable resin precursor component], from the range of from 1/99 to 90/10, and is preferably from 5/95 to 70/30 (for example, from 10/90 to 50/50) and more preferably about from 15/85 to 40/60 (in particular, from 20/80 to 30/70) from the viewpoint of mechanical properties.

### Method for Manufacturing Transfer Mold Releasing Film and Characteristics Thereof

The transfer mold releasing film according to an embodiment of the present invention is not particularly limited as long as the concavo-convex shape can be formed without using fine particles, but when the concavo-convex layer is formed of the curable composition, the transfer mold releasing film may be obtained through coating a curable composition including one or more polymer components and one or more curable resin precursor components onto the base layer and drying the curable composition, wherein the process may include phase-separating at least two components selected from the polymer component and the curable resin precursor component by the wet spinodal decomposition and curing the phase-separated curable composition with heat or active energy rays.

In the phase-separating, the curable composition may include a solvent. The solvent can be selected according to the type and solubility of the polymer component and the curable resin precursor component, and may be at least a solvent which can uniformly dissolve a solid content (for example, a plurality of polymer components and a curable resin precursor component, a reaction initiator, and other additives). In particular, the phase separation structure may be controlled by adjusting the solubility of the solvent with regard to the polymer component and the curable resin precursor component. Examples of such solvents include ketones (acetone, methyl ethyl ketone, methyl isobutyl ketone, and cyclohexanone), ethers (dioxane and tetrahydrofuran), aliphatic hydrocarbons (hexane), alicyclic hydrocarbons (cyclohexane), aromatic hydrocarbons (toluene and xylene), halogenated carbons (dichloromethane and dichloroethane), esters (methyl acetate, ethyl acetate, and butyl acetate), water, alcohols (ethanol, isopropanol, butanol, and cyclohexanol), cellosolves [methyl cellosolve, ethyl cellosolve, and propylene glycol monomethyl ether (1-methoxy-2-propanol)], cellosolve acetates, sulfoxides (dimethyl sulfoxide), and amides (dimethylformamide and dimethylacetamide). In addition, the solvent may be a mixed solvent.

Among these solvents, ketones such as methyl ethyl ketone are preferable, and mixed solvent of ketones with alcohols (butanol and the like) and/or cellosolves (1-methoxy-2-propanol and the like), in particular, mixed solvent of ketones with alcohols, is particularly preferable. In the mixed solvent, the ratio of alcohols and/or cellosolves (the total amount when both are mixed) is from 5 to 150 parts by weight, preferably from 10 to 100 parts by weight, and more preferably about from 15 to 80 parts by weight based on 100 parts by weight of ketones. In particular, when the ketones and the alcohols are combined, the ratio of the alcohols is from 5 to 50 parts by weight, preferably from 8 to 30 parts by weight, and more preferably about from 10 to 20 parts by weight based on 100 parts by weight of ketones. In an embodiment of the present invention, the phase separation can be adjusted by the spinodal decomposition by the appropriate combination with the solvent to form the low gloss concavo-convex shape.

A concentration of a solute (polymer component, curable resin precursor component, reaction initiator, and other additives) in the mixed solution can be selected within the range in which the phase separation occurs and within the range in which flow casting properties and coating properties are not impaired, and is, for example, from 5 to 80% by weight, preferably from 10 to 70% by weight, and more preferably about from 20 to 50% by weight (in particular, from 30 to 40% by weight).

Examples of the coating method include the known methods such as a roll coater, an air knife coater, a blade coater, a rod coater, a reverse coater, a bar coater, a comma coater, a dip squeeze coater, a die coater, a gravure coater, a micro gravure coater, a silk screen coater method, a dip method, a spray method, and a spinner method. Among these methods, the bar coater method or the gravure coater method are widely used. As necessary, the coating solution may be applied a plurality of times.

After the mixed solution is flow-cast or applied, the phase separation by the spinodal decomposition can be induced by evaporating the solvent at a temperature lower than a boiling point of the solvent (for example, temperature that is from 1 to 120° C., preferably from 5 to 50° C., and particularly preferably about from 10 to 50° C. lower than the boiling point of the solvent). The solvent can be evaporated by being usually dried at a temperature of, for example, from 30 to 200° C. (for example, from 30 to 100° C.), preferably from 40 to 120° C., and more preferably about from 50 to 90° C. depending on the boiling point of the solvent.

Regularity or periodicity can be imparted to an average distance between the domains of the phase separation structure by such spinodal decomposition accompanied by the evaporation of the solvent.

In the curing, the dried curable composition is finally cured by active rays (ultraviolet rays, electron beams, and the like) or heat, so the phase separation structure formed by the spinodal decomposition can be promptly fixed. The curable composition may be cured by a combination of heating, light irradiation, and the like according to the type of the curable resin precursor component.

The heating temperature can be selected from an appropriate range, for example, about from 50 to 150° C. The light irradiation can be selected according to the type of the photocuring component or the like, and usually, ultraviolet rays, electron beams, and the like can be used. A general-purpose exposure source is usually an ultraviolet irradiation device.

Examples of the light source include a deep UV lamp, a low-pressure mercury lamp, a high-pressure mercury lamp, an ultrahigh-pressure mercury lamp, a halogen lamp, and a laser light source (light source such as a helium-cadmium laser and an excimer laser) in the case of the ultraviolet rays. The amount of irradiation light (irradiation energy) varies depending on the thickness of the coating film, and is, for example, from 10 to 10000 mJ/cm², preferably from 20 to 5000 mJ/cm², and more preferably about from 30 to 3000 mJ/cm². As necessary, the light irradiation may be performed in an inert gas atmosphere.

In the obtained transfer mold releasing film, when the base layer is formed of a transparent base layer, a transfer mold transparent film has a high haze, and the haze may be 50% or greater (for example, from 50 to 100%), for example, from 60 to 99%, preferably from 65 to 98%, and more preferably about from 70 to 95% (in particular, from 75 to 93%).

### Method for Manufacturing Matte Molded Body

According to an embodiment of the present invention, the low gloss matte molded body is manufactured through providing the transfer surface of the transfer mold releasing film as the mold (negative type), and transferring the concavo-convex shape, which is the inverted shape of the transfer surface, to the surface to be transferred of the molded body.

The obtained matte molded body can be used as a molded body in various fields, for example, automobile parts, electrical/electronic parts, building materials/piping parts, daily necessities (life)/cosmetic parts, and medical (medical/therapeutic) products. Among those, it can be suitably used as the electromagnetic wave shield film for electrical/electronic parts, for example, mobile electronic devices such as smartphones and tablet PCs.

In the transferring, a raw material for the molded body for forming the molded body having the concavo-convex shape on the surface is, usually, preferably a raw material including a resin component from the viewpoint of productivity. The raw material including the resin component is not particularly limited as long as it has the flexibility to be compliant with the transfer surface of the transfer sheet and can be solidified, but usually a melt of the resin component, a liquid composition including the resin component, and the like are generally used, and the liquid composition including the resin component is preferable from the viewpoint of productivity.

The resin component includes a thermoplastic resin, a curable resin (such as a thermosetting resin and a photocurable resin) and can be appropriately selected depending on the type of the molded body. When the matte molded body is the electromagnetic wave shield film, the resin component may be a photocurable resin. Examples of the photocurable resin include photocurable polyester, a photocurable acrylic resin, photocurable epoxy (meth)acrylate, and photocurable urethane (meth)acrylate. These photocurable resins can be used alone or in combination of two or more. Among those, the photocurable acrylic resin and the photocurable urethane (meth)acrylate are preferable from the viewpoint of the excellent balance between the transparency and the strength.

The method of transferring a concavo-convex shape to a surface to be transferred is not particularly limited as long as it is a method for bringing a raw material for a molded body into contact with the transfer surface, wherein the raw material can be compliant with a concavo-convex shape of a transfer surface of a transfer mold releasing film, solidifying the raw material, and then peeling off the solidified molded body from the transfer mold releasing film, but the known method can be appropriately selected depending on the type of the molded body. In the case of the electromagnetic wave shield film, the specific method may be a method, in which, an uncured curable resin (or a composition including a curable resin) is coated (applied) on a transfer surface of a transfer mold releasing film and cured, and then the cured molded body is peeled off from the transfer mold releasing film. In the case of the photocurable resin, the same method as the method for manufacturing the transfer mold releasing film can be used as the coating method and the curing method for the curable resin, and in the case of the thermosetting resin, the same method as the method for manufacturing the transfer mold releasing film can be used as the coating method, and the method for heating at a temperature corresponding to the type of resin can be used as the curing method.

Generally, in the case of electromagnetic wave shield film, prior to the peeling, the uncured curable resin is coated and then a black curable resin is coated, and a metal layer and an adhesive layer are laminated and the releasing film is laminated on an adhesive layer by the known method. In the case of the known electromagnetic wave shield film, the transfer surface of the transfer film is coated with a release layer and then coated with an uncured curable resin. However, in an embodiment of the present invention, the curable composition is adjusted to a specific combination and thus the transfer mold releasing film itself can be provided with improved peeling characteristic, so the uncured curable resin can be coated without forming the release layer, and productivity can be improved. In addition, even if the electromagnetic wave shield film is excellent in peeling characteristic after the curing of the curable resin, the electromagnetic wave shield film is excellent in workability because it is not peeled before the curing. In an embodiment of the present invention, if necessary, the known release layer (for example, a release layer including a fluorine compound, a silicone compound, a wax, and the like) may be laminated on the transfer surface.

For the obtained matte molded body, in the transfer in which the transfer surface of the transfer mold releasing film is formed as a negative type mold, the concavo-convex shape, in which the shape of the negative type mold is inverted, can be formed. The gloss of the obtained matte molded body is low and the 60° gloss of the surface to be transferred of the matte molded body is less than 5% (for example, from 0.1 to 4.9%), preferably from 1 to 4.5% (for example, from 1.5 to 4.2%), and more preferably about from 2 to 4% (in particular, from 2.5 to 3.5%).

The arithmetic average surface roughness Ra of the surface to be transferred is from 0.1 to 1.0 μm, preferably from 0.2 to 0.8 μm, and more preferably about from 0.3 to 0.7 μm (particularly from 0.3 to 0.5 μm).

### EXAMPLES

Hereinafter, the present invention will be described in more detail based on Examples, but is not limited to these Examples. The raw materials used in Examples and Comparative Examples are as follows, and the obtained transfer mold releasing film was evaluated by the following method.

### Raw Material

Acrylic resin having a polymerizable group: “Cyclomer P (ACA) 320M” available from Daicel Corporation, a compound in which 3,4-epoxycyclohexenylmethyl acrylate is added to a part of carboxyl groups of a (meth)acrylate-(meth)acrylate ester copolymer, a solid content 49.6% by weight

Cellulose acetate propionate (CAP): “CAP-482-20” available from Eastman Chemical Company, degree of acetylation=2.5%, degree of propionylation=46%, number average molecular weight of 75000 based on calibration using polystyrene.

Nanosilica-containing acrylic ultraviolet (UV) curable compound: “UVHC7800G” available from Momentive Performance Materials Japan LLC.

Urethane acrylate: “U-15HA” available from Shin-Nakamura Chemical Co., Ltd., molecular weight of 2300, the number of functional groups of 15

Silicone acrylate: “EB1360” available from Daicel-Allnex Ltd., the number of functional groups of 6, viscosity of 2100 mPa s (25° C.)

Fluorine-containing curable compound: “KY-1203” available from Shin-Etsu Chemical Co., Ltd., acryloyl group-containing fluoropolyether water repellent

Photoinitiator A: “Irgacure 184” available from BASF Japan Ltd.

Photoinitiator B: “Irgacure 907” available from BASF Japan Ltd.

MEK: Methyl ethyl ketone

1-BuOH: 1-butanol

PGM: 1-methoxy-2-propanol

Polyethylene terephthalate (PET) film: “Diafoil” available from Mitsubishi Plastics, Inc.

### 60° Gloss

Measurement was performed at an angle of 60° using a gloss meter (“IG-320” available from Horiba, Ltd.) in accordance with JIS K7105.

### Arithmetic Average Surface Roughness (Ra)

The arithmetic average surface roughness (Ra) was measured using a contact type surface roughness meter (“Surfcom 570A” available from Tokyo Seimitsu Co., Ltd.) under the conditions of a scanning range of 3 mm and the number of scans being 2 times in accordance with JIS B0601.

### Transferability (Peeling Characteristic)

The transfer mold releasing film obtained in the Example was placed in a mold of an all-electric two-material injection molding machine (“SE130DU-CI” available from Sumitomo Heavy Industries, Ltd.) such that the base surface was in contact with the mold. A resin, in which 100 parts by weight of ABS resin (Toyolac, Grade 700-X01 available from Toray Industries, Inc.) and 5 parts by weight of black masterbatch were mixed, was molded by injection-molding at a mold temperature of 60° C. and a resin temperature of 230° C. The product was evaluated whether the transfer mold releasing film and the molded body could be peeled by hand.

### Example 1

The liquid composition shown in Table 1 was prepared, and flow-casted on a PET film using a wire bar #18. Subsequently, the material was left in an oven at 80° C. for 1 minute to evaporate a solvent and form a concavo-convex layer having a thickness of about 8 μm. Then, the concavo-convex layer was irradiated with ultraviolet rays from a high-pressure mercury lamp for about 5 seconds and subjected to UV curing treatment to obtain a transfer mold releasing film.

### Example 2

The liquid composition shown in Table 1 was prepared, and flow-casted on a PET film using a wire bar #20. Subsequently, the material was left in an oven at 80° C. for 1 minute to evaporate a solvent and form a concavo-convex layer having a thickness of about 9 μm. Then, the concavo-convex layer was irradiated with ultraviolet rays from a high-pressure mercury lamp for about 5 seconds and subjected to UV curing treatment to obtain a transfer mold releasing film.

TABLE 1

| | Blending amount (part by weight) | |
|---|---|---|
| | Example 1 | Example 2 |
| Acrylic resin including polymerizable | 45.9 | 12.5 |
| group | | |
| CAP | 3.6 | 4.0 |
| Nanosilica-containing acrylic UV | — | 150.0 |
| curable compound | | |
| Urethane acrylate | 77.0 | — |
| Silicone acrylate | 1.0 | 1.0 |
| Fluorine-containing curable | 0.2 | 0.2 |
| compound | | |
| Photoinitiator A | 1.0 | 1.0 |
| Photoinitiator B | 1.0 | 1.0 |
| MEK | 178.0 | 89.0 |
| 1-BuOH | 28.0 | 24.0 |
| PGM | — | 13.0 |

After the 60° gloss and the arithmetic average surface roughness (Ra) of the transfer surface of the obtained transfer mold releasing film were measured, a transfer test was performed, and peeling characteristic was evaluated, and then the 60° gloss of surface to be transferred was measured. The results are shown in Table 2.

TABLE 2

| | Example 1 | Example 2 |
|---|---|---|
| 60° gloss of transfer mold releasing film | 3.0 | 3.0 |
| 60° gloss of body to be transferred | 3.0 | 3.0 |
| Ra of transfer mold releasing film | 0.5 | 0.9 |
| Peeling characteristic | Easily peeled | No peeling |

As is clear from the results in Table 2, the body to be transferred obtained in any of the Examples also had low gloss. Furthermore, the releasing film obtained in Example 1 had good peeling characteristic.

### INDUSTRIAL APPLICABILITY

The transfer mold releasing film according to an embodiment of the present invention can be used for the matte molded body of various fields, for example, automobile parts, electrical/electronic parts, building materials/piping parts, daily necessities (life)/cosmetic parts, and medical (medical/therapeutic) products. Among these, the transfer mold releasing film can be suitably used to manufacture the electromagnetic wave shield film for electrical/electronic parts, for example, mobile electronic devices such as smartphones and tablet PCs.

1. A transfer mold releasing film for manufacturing a matte molded body with low gloss by transfer, the transfer mold releasing film comprising:
a base layer, and a concavo-convex layer that is formed on at least one surface of the base layer and has a surface that is a transfer surface,
wherein the concavo-convex layer does not include fine particles of 1 μm or greater, and an arithmetic average roughness Ra of the transfer surface is from 0.1 to 2 μm, and 60° gloss of the transfer surface is less than 5%.

2. The transfer mold releasing film according to claim 1, wherein the concavo-convex layer is a cured product of a curable composition including one or more polymer components and one or more curable resin precursor components.

3. The transfer mold releasing film according to claim 2, wherein at least two components selected from the polymer components and the curable resin precursor components are phase-separable by wet spinodal decomposition, the polymer components include cellulose esters and a (meth)acrylate-based polymer which optionally includes a polymerizable group, and the curable resin precursor components include urethane (meth)acrylate, silicone (meth)acrylate, and a fluorine-containing curable compound.

4. The transfer mold releasing film according to claim 1, wherein a haze is 50% or greater.

5. The transfer mold releasing film according to claim 1, wherein the concavo-convex layer does not include fine particles.

6. A method for manufacturing a matte molded body, the method comprising: performing transferring to form a concavo-convex shape on a surface to be transferred of the molded body using the transfer surface of the transfer mold releasing film described in claim 1 as a mold, the concavo-convex shape being an inverted shape of the transfer surface.

7. The method for manufacturing a matte molded body according to claim 6, wherein the matte molded body is an electromagnetic wave shield film.
